(19) United States
(12) Patent Application Publication
(10) Pub. No.: US 2002/0060371 A1
(43) Pub. Date: May 23, 2002

(54) High-power semiconductor module, and use of such a high-power semiconductor module

(76) Inventor: Thomas Lang, Zurich (CH)

Correspondence Address: Robert S. Swecker, BURNS, DOANE, SWECKER & MATHIS, L.L.P., P.O. Box 1404, Alexandria, VA, 22313-1404, US

(21) Appl. No.: 09/988,540

(22) Filed: Nov. 20, 2001

(30) Foreign Application Priority Data
Nov. 22, 2000 (EP) 00811110.6

(51) Int. Cl. H01L 23/48

(52) U.S. Cl. 257/785

(57) ABSTRACT

A high-power semiconductor module (10) has a number of flat semiconductor chips (14) which rest with their lower face flat on a base plate (11), establishing first electrical contacts, and have a cover plate (13), which is arranged parallel to the base plate (11), applied to their upper face with pressure, establishing second electrical contacts.

In a module such as this, simplified cooling is made possible in that those faces, or outer faces, of the base plate (11) and of the cover plate (13) which face away from the semiconductor chips (14) are each electrically isolated from the semiconductor chips (14).

### TECHNICAL FIELD

The present invention relates to the field of power electronics. It relates in particular to a high-power semiconductor module as claimed in the precharacterizing clause of claim 1.

A high-power semiconductor module of this type is known, for example, from an article by H. Zeller, “High Power Components—From the State of the Art to Future Trends”, PCIM Nuremberg, May 1998 (FIG. 3).

### PRIOR ART

Widely different versions of high-power semiconductor modules are known from the prior art (see, for example, EP-A1-0 597 144, U.S. Pat. No. 5,978,220 or 6,087,682).

High-power semiconductor modules are operated at voltages up to 10 kV per module. Voltages of well above 100 kV are reached by connecting them in series (for example for high-voltage direct-current transmission). Water or water/glycol is generally used to cool such modules efficiently. The coolers used for this purpose are—in a comparable manner to the configuration described in U.S. Pat. No. 4,574,877—connected in series with the modules in a stack to which pressure is applied, and are accordingly likewise at high potentials. The coolers must be operated using deionized water since, otherwise, current could flow to lower potentials via the cooling medium. The requirement to be able to connect such modules in series means that they are constructed in such a way that the one end surface corresponds to the emitter potential, and the opposite surface corresponds to the collector potential. A more recent version of such a module, in which a number of IGBT chips are connected in parallel within the module in a “press pack” configuration, is illustrated and described in the article by H. Zeller mentioned initially. The press pack configuration, in which the electric connection for the semiconductor chips arranged in the module is established by means of a pressure contact, has the advantage over making contact by means of bonding wires that, in the event of a fault, there is a stable short circuit in the module, so that this avoids any interruption in the current flow in a series circuit in this case.

In other applications (for example for traction), the initial situation is somewhat different: here, lower voltages are used, so that there is no need to connect the modules directly in series. However, on the other hand, deionized water must not be used since this can lead to complications in this application. For this reason, modules such as these should be isolated from the cooling medium.

This is typically achieved by using AlN substrates within the module and/or by introducing large AlN plates between the semiconductor module and the cooler. AlN coolers are even used in certain situations. Such isolated modules unfortunately frequently have restricted reliability (thermal expansion between the base plate and the substrates), while the large AlN plates and coolers are very expensive.

### DESCRIPTION OF THE INVENTION

The object of the invention is thus to provide a high-power semiconductor module which links the increased reliability of pressure-contact modules with the capability to use a cooler through which industrial water flows, and to specify an application for such a high-power semiconductor module.

The object is achieved by the totality of features in claims 1 and 13. The essence of the invention is to design the module at the same time using a press pack configuration, and to configure the outer faces of the module such that they are electrically isolated from the semiconductor chips accommodated in the module. This results in DC isolation from an externally located cooling apparatus, while at the same time making reliable contact.

One preferred refinement of the invention is distinguished in that a first electrically conductive, elastic connecting element, preferably in the form of a first contact spring, is in each case arranged between the upper face of the semiconductor chips and the cover plate, in that the base plate is an electrically insulating substrate which has a first metal coating on the inner face, in that the semiconductor chips are mounted by techniques such as bonding, soldering or welding, preferably by soldering, on the first metal coating, in that the first metal coating has the cover plate applied to it, with pressure, in an area located outside the semiconductor chips, establishing a third electrical contact, and in that the third electrical contact is established via a second electrically conductive, elastic connecting element, preferably in the form of a second contact spring.

One preferred development of this refinement is characterized in that the cover plate is a first isolation plate, on whose inner face a first metallic contact plate is arranged, via which the second electrical contacts with the semiconductor chips are established, and in that a second metallic contact plate is arranged on the first metallic contact plate, and electrically isolated from it, via which the third electrical contact with the first metal coating on the base plate is established.

In order to provide further protection for the module, an electrically insulating housing is arranged between the base plate and the cover plate, and encloses the semiconductor chips and the associated contact devices.

Further embodiments can be found in the dependent claims.

### BRIEF EXPLANATION OF THE FIGURES

The invention will be explained in more detail in the following text with reference to exemplary embodiments and in conjunction with the drawing, in which:

FIG. 1 shows a plan view, from above, of the base plate with the semiconductor chips and contact springs, as well as the surrounding housing of one preferred exemplary embodiment of the invention;

FIG. 2 shows a longitudinal section of the cover plate associated with the module shown in FIG. 1; and

FIG. 3 shows a longitudinal section through a completely assembled module as shown in FIGS. 1 and 2, and its use in a stack with a cooling apparatus.

### APPROACHES TO IMPLEMENTATION OF THE INVENTION

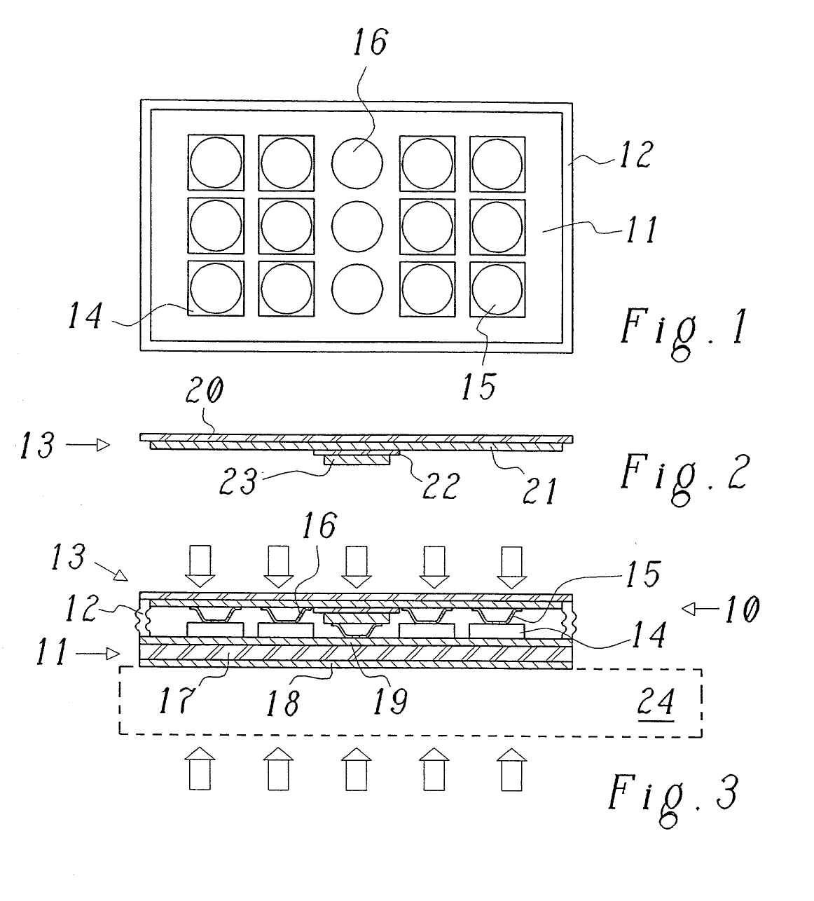

FIG. 3 shows a longitudinal section through a high-power semiconductor module 10 according to one preferred exemplary embodiment of the invention. The module has a base plate 11, on whose upper face (inner face) as shown in FIG. 1 a number of semiconductor chips 14 (a total of 12 in the example) are fitted in a regular arrangement of four rows of three chips each. An electrically insulating housing 12 (preferably made of plastic) is provided at the edges around the semiconductor chips 14, and this housing 12 can be compressed in the vertical direction by means of suitable measures (for example transverse corrugation). The high-power semiconductor module 10 is closed at the top by a cover plate 13 (see also FIG. 2). First contact springs 15 are arranged between the cover plate 13 and the free upper faces of the semiconductor chips 14, via which first contact springs 15 (with appropriate pressure) an electrical contact is made between the cover plate 13 and the semiconductor chips 14. Second contact springs 16, which are placed between the two groups of six semiconductor chips 14, provide a corresponding pressure contact between the cover plate 13 and the base plate 11.

An electrically insulating substrate 17 (for example AlN or some other ceramic) is used as the base plate 11, and is provided on both the upper face and lower face with a respective metal coating 19 and 18. The semiconductor chips 14 are soldered to the upper metal coating 19 on the base plate 11, with space being left free for the second contact springs 16. If the semiconductor chips 14 are, for example, IGBTs, these are soldered on the collector side. The emitter metalization of each semiconductor chip 14 is now fitted with a sprung contact (first contact spring 15). The contact springs 15, which are in the form of pots in the illustrated example, may assume widely different shapes, provided the spring pressure is sufficiently great and the contact surface areas are sufficient for the specified high currents. The free surface areas of the upper metal coating 19 are provided with comparable second contact springs 16. Thus, in the illustrated example, the central three contact springs 16 are at the collector potential, and the outer twelve contact springs 15 (of the semiconductor chips 14) are at the emitter potential. These two potentials or voltages can now be tapped off from above by means of the cover plate 13.

The cover plate 13 has a sandwich structure (FIG. 2): a narrow collector contact plate 23 (collector busbar) is bonded—isolated by an isolation plate 22—onto a large-area emitter contact plate 21 (emitter busbar) The emitter contact plate 21 is itself isolated from the exterior by means of a further isolation plate 20. The collector contact plate 23 presses against the central contact springs 16, and thus makes contact via the upper metal coating with the collector side of the semiconductor chips 14. The emitter contact plate 21 presses against the contact springs 15 which are arranged on the semiconductor chips 14, and thus makes contact with the emitter side of the semiconductor chips 14. Appropriately shaped contact lugs may be passed out of the housing 12 at the side from both contact plates 21 and 23, and may be used as electrical connections for the module.

The illustrated high-power semiconductor module 10 may now, as shown in FIG. 3, be stacked in a pressing apparatus, in which case only the base plate 11 need be cooled. A cooling apparatus 24 (represented by dashed lines in FIG. 3) is used for this purpose, and its cold surface rests against the lower metal coating 18 on the base plate 11. Pressure is exerted on both sides of the stack (arrows in FIG. 3) to ensure both the electrical pressure contacts in the interior of the module and the thermal contact between the base plate 11 and the cooling apparatus 24. A cooling box, which is known per se and through which water flows, may be used, for example, as coling apparatus 24.

1. A high-power semiconductor module (10), in which a number of flat semiconductor chips (14) rest with their lower face flat on a base plate (11), establishing first electrical contacts, and have a cover plate (13), which is arranged parallel to the base plate (11), applied to their upper face with pressure, establishing second electrical contacts, characterized in that those faces, or outer faces, of the base plate (11) and of the cover plate (13) which face away from the semiconductor chips (14) are each electrically isolated from the semiconductor chips (14).

2. The high-power semiconductor module as claimed in claim 1, characterized in that a first electrically conductive, elastic connecting element, preferably in the form of a first contact spring (15), is arranged between the upper face of each semiconductor chip (14) and the cover plate (13).

3. The high-power semiconductor module as claimed in one of claims 1 or 2, characterized in that the base plate (11) comprises an electrically insulating substrate (17) which has a first metal coating (19) on the inner face, and in that the semiconductor chips (14) are mounted, preferably by techniques such as bonding, soldering or welding, preferably by soldering, on the first metal coating (19).

4. The high-power semiconductor module as claimed in claim 3, characterized in that the substrate (17) is composed of a ceramic, preferably an AlN ceramic.

5. The high-power semiconductor module as claimed in one of claims 3 or 4, characterized in that the base plate (11) is provided with a second metal coating (18) on the outer face.

6. The high-power semiconductor module as claimed in one of claims 3 to 5, characterized in that, in an area located outside the semiconductor chips (14), pressure is applied to the first metal coating (19) by the cover plate (13), thus establishing a third electrical contact.

7. The high-power semiconductor module as claimed in claim 6, characterized in that the third electrical contact is established via a second electrically conductive, elastic connecting element, preferably in the form of a second contact spring (16).

8. The high-power semiconductor module as claimed in one of claims 6 or 7, characterized in that the cover plate (13) comprises a first isolation plate (20), on whose inner face a first metallic contact plate (21) is arranged, via which the second electrical contacts with the semiconductor chips (14) are established, and in that a second metallic contact plate (23) is arranged on the first metallic contact plate (21), and electrically isolated from it, via which the third electrical contact with the first metal coating (19) on the base plate (11) is established.

9. The high-power semiconductor module as claimed in claim 8, characterized in that the first and the second metallic contact plates (21 and 23, respectively) are isolated from one another by a second isolation plate (22).

10. The high-power semiconductor module as claimed in one of claims 1 to 9, characterized in that an electrically insulating housing (12) is arranged between the base plate (11) and the cover plate (13), and encloses the semiconductor chips (14) and the associated contact devices (15, 16).

11. The high-power semiconductor module as claimed in one of claims 1 to 10, characterized in that the semiconductor chips (14) are connected electrically in parallel within the high-power semiconductor module (10).

12. The high-power semiconductor module as claimed in claim 11, characterized in that at least some of the semiconductor chips (14) are controllable semiconductor switches, in particular IGBTs.

13. Use of a high-power semiconductor module as claimed in one of claims 1 to 12 in a power-electronics system, in which the high-power semiconductor module (10) is arranged together with a cooling apparatus (24), which is adjacent to the outer face of the base plate (11), to form a stack, and pressure is applied to it in the stack.
